(19) United States
(12) Patent Application Publication
(10) Pub. No.: US 2010/0136465 A1
(43) Pub. Date: Jun. 3, 2010

(54) Method of fabricating photomask

(76) Inventors: Mi-Hye Ahn, Seo-gu (KR); Dongseok Nam, Yongin-si (KR)

Correspondence Address: LEE & MORSE, P.C., 3141 FAIRVIEW PARK DRIVE, SUITE 500, FALLS CHURCH, VA, 22042, US

(21) Appl. No.: 12/591,104

(22) Filed: Nov. 9, 2009

(30) Foreign Application Priority Data
Nov. 28, 2008 (KR) 10-2008-0119679

(51) Int. Cl. G03F 1/00

(52) U.S. Cl. 430/5

(57) ABSTRACT

A method of fabricating a photomask including forming a light-shielding pattern on a substrate, determining whether a critical dimension (CD) of the light-shielding pattern deviates by at least a predetermined amount from a predetermined CD range, and correcting the CD of the light-shielding pattern if the CD of the light-shielding pattern deviates by at least the predetermined amount from the predetermined CD range, wherein the correcting the CD of the light-shielding pattern includes selectively liquid-treating the light-shielding pattern having a CD deviating by at least the predetermined amount from the predetermined CD range.

### BACKGROUND

1. Field

Embodiments relate to a method of fabricating a photomask.

2. Description of the Related Art

With high degrees of integration of semiconductor devices, a photolithography process capable of forming a finer pattern is desirable. In general, a photolithography process may use a photomask to form a pattern on a semiconductor substrate. The photomask may include, e.g., a binary mask and/or a phase shift mask (PSM). The photomask may include, e.g., a quartz substrate having a light-shielding or phase-shift pattern thereon. A pattern to be formed on the semiconductor substrate may be determined according to a critical dimension (CD) of the light-shielding or phase-shift pattern of the photomask.

### SUMMARY

Embodiments are directed to a method of fabricating a photomask, which substantially overcomes one or more of the drawbacks, limitations, and/or disadvantages of the related art.

It is a feature of an embodiment to provide a method of fabricating a photomask that effectively corrects a critical dimension (CD) of a light-shielding pattern deviating by at least a predetermined amount from a predetermined CD range.

It is another feature of an embodiment to provide a method of fabricating a photomask that increases the efficiency of a semiconductor fabrication process.

At least one of the above and other features and advantages may be realized by providing a method of fabricating a photomask including forming a light-shielding pattern on a substrate, determining whether a critical dimension (CD) of the light-shielding pattern deviates by at least a predetermined amount from a predetermined CD range, and correcting the CD of the light-shielding pattern if the CD of the light-shielding pattern deviates by at least the predetermined amount from the predetermined CD range, wherein the correcting the CD of the light-shielding pattern includes selectively liquid-treating the light-shielding pattern having a CD deviating by at least the predetermined amount from the predetermined CD range.

The liquid-treating of the light-shielding pattern may be performed using a nozzle that has a sprayer configured to spray a liquid onto the substrate and an inhaler configured to inhale the liquid on the substrate.

The determining whether the CD of the light-shielding pattern deviates by at least the predetermined amount from the predetermined CD range may include determining whether the CD of the light-shielding pattern is greater by at least the predetermined amount than a predetermined CD.

The liquid-treating of the light-shielding pattern may include supplying an etchant onto the substrate, the etchant including at least one of sulfuric acid (H₂SO₄), hydrogen peroxide (H₂O₂), and water including a gas dissolved therein including at least one of hydrogen (H₂), ozone (O₃), and ammonia (NH₃).

The etchant may reduce the CD of the light-shielding pattern.

The forming the light-shielding pattern on the substrate may include sequentially forming a light-shielding layer and a photoresist pattern on the substrate; and etching the light-shielding layer using the photoresist pattern as an etch mask.

The forming the light-shielding pattern on the substrate may include forming a phase shift layer, a light-shielding layer, and a photoresist pattern on the substrate; and etching the light-shielding layer using the photoresist pattern as an etch mask.

The method may further include forming a phase-shift pattern by etching the phase shift layer after the liquid-treating the light-shielding pattern using the light-shielding pattern, which has been corrected to satisfy the predetermined CD range, as an etch mask.

The method may further include removing the light-shielding pattern from the phase-shift pattern.

At least one of the above and other features and advantages may also be realized by providing a method of fabricating a photomask including forming light-shielding patterns including a first light-shielding pattern and a second light-shielding pattern on a substrate; and correcting the second light-shielding patterns by supplying an etchant onto the substrate, wherein the first light-shielding pattern satisfies a predetermined CD range and the second light-shielding pattern deviates by at least a predetermined amount from the predetermined CD range, and the correcting the light-shielding patterns includes removing the etchant supplied to the first light-shielding pattern and reducing a CD of the second light-shielding pattern with the etchant.

The removing the etchant supplied to the first light-shielding pattern may be performed using a nozzle with an inhaler configured to inhale the etchant.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a flow chart of a method of fabricating a photomask according to an embodiment;

FIGS. 2A to 2C illustrate sectional views of stages in a method of fabricating a photomask according to an embodiment;

FIG. 3A illustrates a diagram of a nozzle according to an embodiment;

FIG. 3B illustrates a diagram of a nozzle unit according to an embodiment;

FIG. 4 illustrates a flow chart of a method of fabricating a photomask according to another embodiment; and

FIGS. 5A through 5D illustrate sectional views of stages in a method of fabricating a photomask according to another embodiment.

### DETAILED DESCRIPTION

Korean Patent Application No. 10-2008-0119679, filed on Nov. 28, 2008, in the Korean Intellectual Property Office, and entitled: “Method of Treating Photomask,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

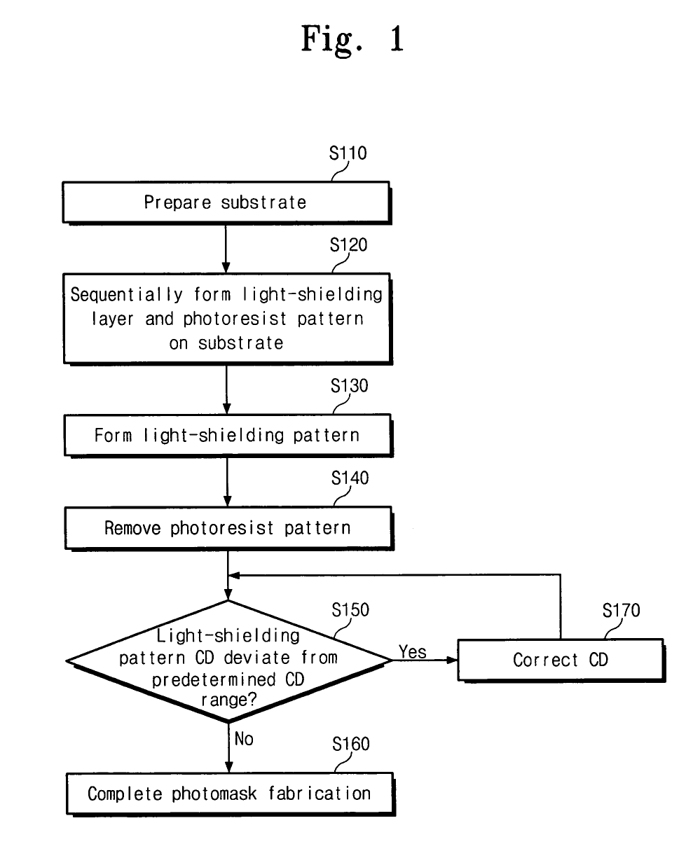

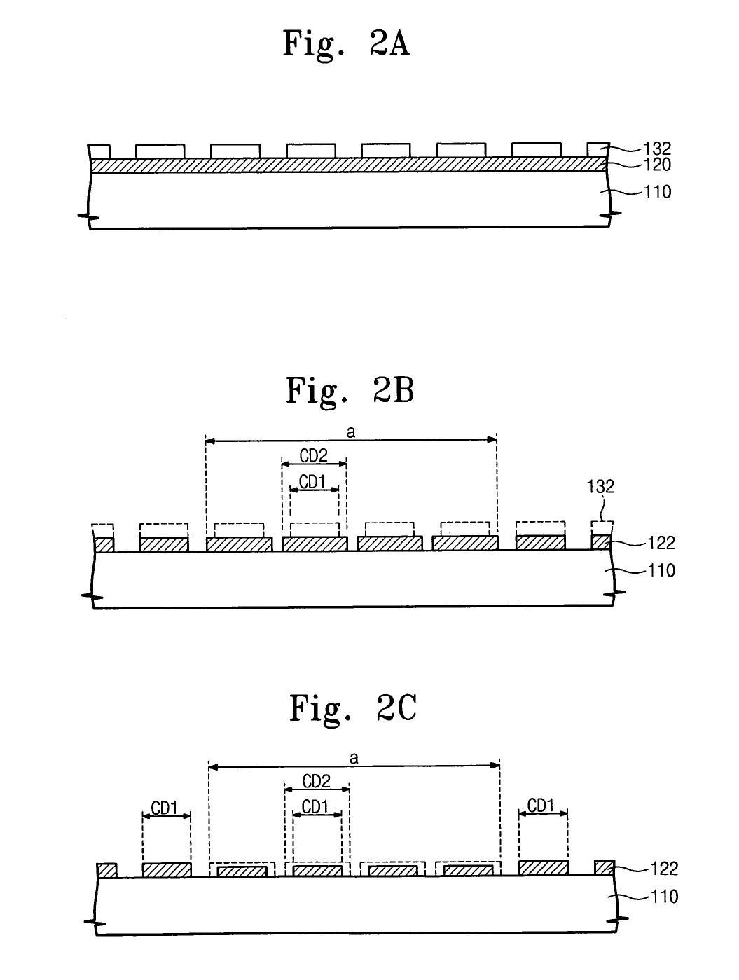

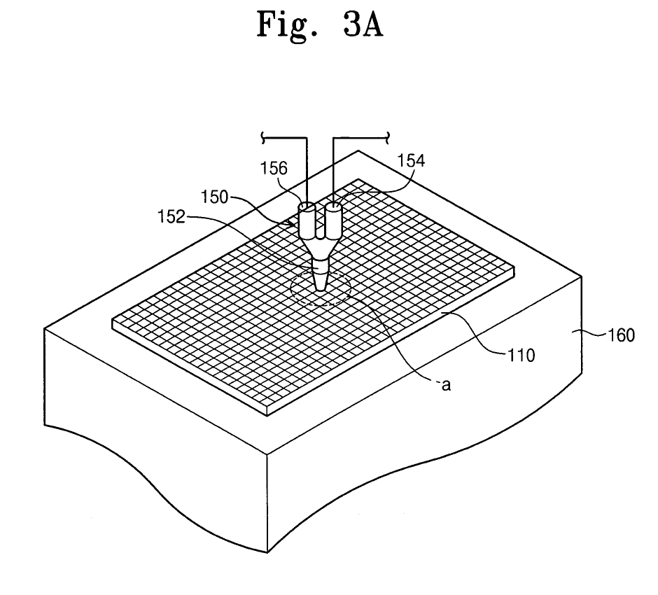

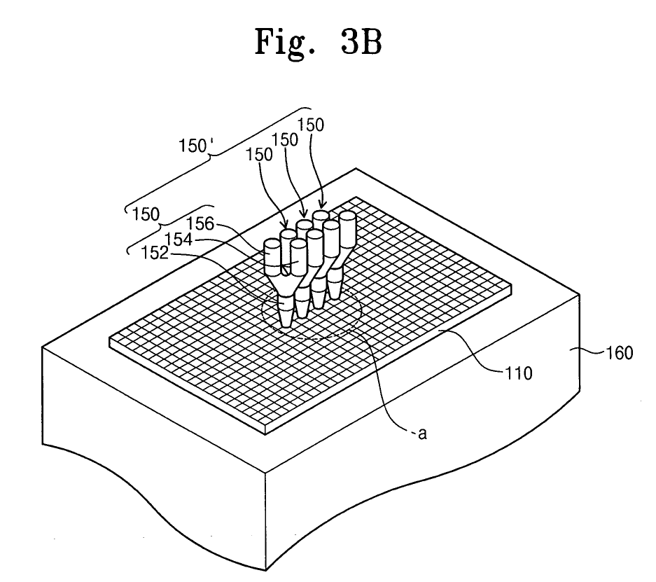

Herein, a method of fabricating a photomask according to an embodiment will be described in detail. FIG. 1 illustrates a flow chart of a method of fabricating a photomask according to an embodiment. FIGS. 2A to 2C illustrate sectional views of stages in a method of fabricating a photomask according to the embodiment. FIG. 3A illustrates a diagram of a nozzle according to an embodiment. FIG. 3B illustrates a diagram of a nozzle unit according to an embodiment.

Referring to FIGS. 1 and 2A, a substrate 110 may be prepared (S110). The substrate 110 may include, e.g., a photomask substrate for a semiconductor exposure process. The substrate 110 may be formed of, e.g., quartz. The photomask fabricated by the method of the present embodiment may be, e.g., a binary mask.

A light-shielding layer 120 and a photoresist pattern 132 may be sequentially formed on the substrate 110 (S120). The forming of the light-shielding layer 120 may include forming a metal layer, e.g., a chromium (Cr) layer, on the substrate 110. The light-shielding layer 120 may prevent light from penetrating the substrate 110 during an exposure process. The forming of the photoresist pattern 132 may include forming a photoresist layer on the light-shielding layer 120 and patterning the photoresist layer.

Referring to FIGS. 1 and 2B, a light-shielding pattern 122 may be formed on the substrate 110 (S130). The forming of the light-shielding pattern 122 may include, e.g., removing a portion of the light-shielding layer 120 to expose portions of the substrate 110. The removing a portion of the light-shielding layer 120 may include, e.g., dry-etching the light-shielding layer 120 by using the photoresist pattern 132 as an etch mask.

After formation of the light-shielding pattern 122, the photoresist pattern 132 may be removed (S140). The removing of the photoresist pattern 132 may include, e.g., wet-cleaning the surface of the substrate 110 having the light-shielding pattern 122 formed thereon. The light-shielding pattern 122 formed through the above process may have a defective pattern deviating by at least a predetermined amount (hereinafter, “deviating”) from a predetermined critical dimension (CD) range. A region ‘a’ having the light-shielding pattern 122 with a critical dimension CD2 greater than a predetermined critical dimension CD1 (hereinafter, “correction region”) may be present on the substrate 110.

After removal of the photoresist pattern 132, it may be determined whether the CD of the light-shielding pattern 122 on the substrate 110 satisfies the predetermined CD range (S150). Herein, the determining of whether the CD of the light-shielding pattern 122 satisfies the predetermined CD range may include determining whether the CD of the light-shielding pattern 122 is greater than the predetermined CD. The CD of the light-shielding pattern 122 may be measured by a CD measurement device (not illustrated). The CD measurement device may include, e.g., a Scanning Electron Microscope (SEM) measurement device and/or an Optical Critical Dimension (OCD) measurement device. The CD measurement device may measure the CD of the light-shielding pattern 122 formed on the substrate 110. The data measured by the CD measurement device may be transmitted to a controller (not illustrated). The controller may determine whether the CD of the light-shielding pattern 122 measured by the CD measurement device satisfies the predetermined CD range. For example, standard data, i.e., reference data, for the predetermined CD range may be stored in the controller. Accordingly, the controller may determine whether the measured CD of the light-shielding pattern 122 deviates from the predetermined CD range, by, e.g., comparing the data received from the CD measurement device with the reference data. If the CD of the light-shielding pattern 122 measured by the CD measurement device satisfies the de predetermined sired CD range, the photomask fabrication may be completed (S160).

Referring to FIGS. 1 and 2C, if the CD of the light-shielding pattern 122 measured by the CD measurement device deviates from the predetermined CD range, the CD of the light shielding pattern 122 may be corrected (S170). The correcting of the CD may include, e.g., liquid-treating the substrate 110 having the light-shielding pattern 122 thereon (hereinafter, the “pre-photomask”). The liquid-treating of the pre-photomask may include, e.g., supplying an etchant onto the pre-photomask. The etchant may include, e.g., a liquid capable of etching the light-shielding pattern 122. In addition, the etchant may be used as a cleaning liquid capable of removing foreign materials on the photomask. The etchant may include, e.g., sulfuric acid (H₂SO₄), hydrogen peroxide (H₂O₂), and/or water containing a gas dissolved therein, including at least one of hydrogen (H₂), ozone (O₃), and ammonia (NH₃). The etchant may isotropically etch the light-shielding pattern 122 in the correction region ‘a’. Accordingly, the critical dimension CD2 of the light-shielding pattern 122 in the correction region ‘a’ may decrease to the predetermined critical dimension CD1.

The liquid-treating of the pre-photomask may be performed through, e.g., a single-substrate treating process. For example, referring to FIG. 3A, the liquid-treating of the pre-photomask may include disposing the photomask on a support member 160 and supplying the etchant onto the pre-photomask supported by the support member 160. The support member 160 may include, e.g., a chuck capable of supporting the pre-photomask. The supplying of the etchant onto the pre-photomask may be performed using, e.g., a nozzle. In an implementation, the supplying of the etchant onto the pre-photomask may be performed using a nozzle 150 having an inhaler 156. The nozzle 150 may also include a sprayer 152 configured to spray an etchant and a supplier 154 configured to supply the etchant to the sprayer 152. The inhaler 156 may inhale the etchant supplied to the pre-photomask by the sprayer 152. Accordingly, the inhaler 156 may prevent the etchant, supplied to the pre-photomask, from etching a region other than the correction region ‘a’. In other words, the inhaler 156 may remove the etchant from portions of the pre-photomask other than the correction region ‘a’ to thereby prevent etching of the pre-photomask in regions other than the correction region ‘a’.

Referring to FIG. 3B, in an implementation, the supplying of the etchant onto the pre-photomask may be performed using a nozzle unit 150′ including a plurality of nozzles 150. Each of the nozzles 150 may be identical or similar in structure to the nozzle 150 of FIG. 3A. For example, each of the nozzles 150 may include a sprayer 152, a supplier 154, and an inhaler 156. The nozzles 150 may be driven by, e.g., a drive unit (not illustrated). In an implementation, the drive unit may move the nozzles 150 freely on the pre-photomask when the etchant is supplied onto the pre-photomask.

The liquid-treating of the pre-photomask may be selectively performed in the correction region ‘a’. Specifically, the liquid-treating of the pre-photomask may be performed only on a region having a defective pattern (among the light-shielding patterns 122) deviating from the predetermined CD range (i.e., the correction region ‘a’), and may not be performed on a region of the pre-photomask having a good pattern (among the light-shielding patterns 122), i.e., satisfying the predetermined CD range. For example, as described above, the nozzles 150 may include an inhaler 156 that prevents the etchant from etching a region other than the correction region ‘a’. That is, the inhaler 156 may inhale and remove the etchant supplied to the good pattern on the pre-photomask. Accordingly, the nozzles 150 may inhale and remove the etchant supplied to the good pattern, thereby making it possible to selectively supply the etchant to, and only etch in, the correction region ‘a’. Also, in the liquid-treating process, the drive unit may move the nozzles 150 so that the liquid-treating process is performed only on the correction region ‘a’. Thus, the moving direction and path of the nozzles 150 by the drive unit may vary depending on the size and shape of the correction region ‘a’.

As described above, the method of an embodiment may correct a defective pattern on the substrate 110, which may deviate from the predetermined CD range, into a suitable pattern by, e.g., liquid-treating the defective pattern. The above CD correction may be performed by selectively supplying the etchant onto a region of the photomask having the light-shielding pattern that deviates from the predetermined CD range. The supplying of the etchant only onto the region of the photomask may be performed using the nozzle 150 having the inhaler 156.

Herein, a method of fabricating a photomask according to another embodiment will be described in detail. Repeated description of material that overlaps with the aforesaid embodiment will be omitted.

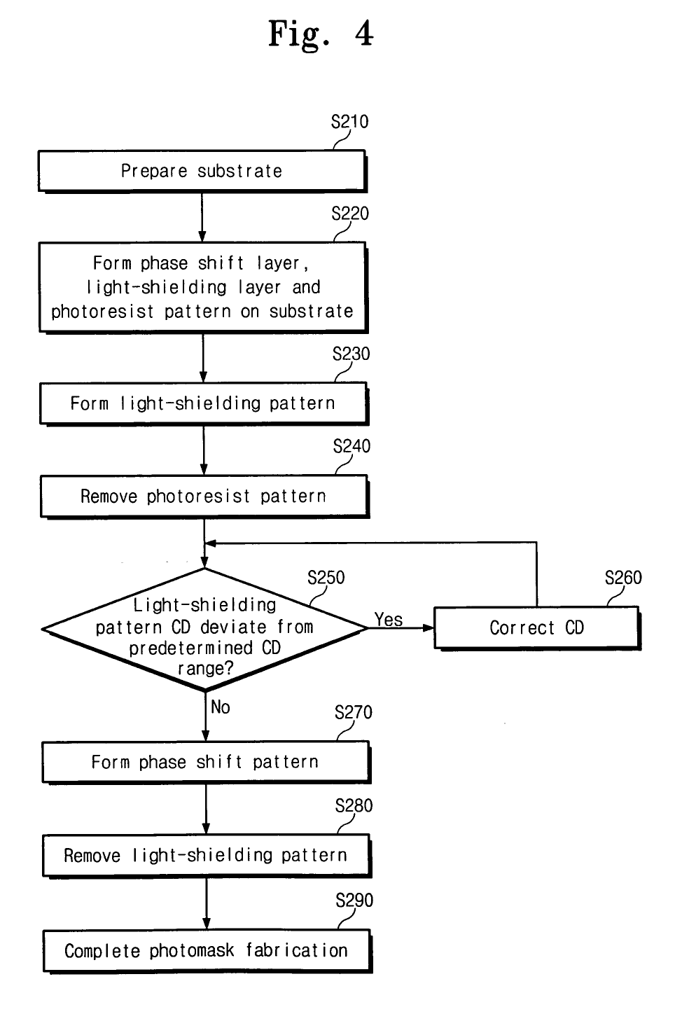

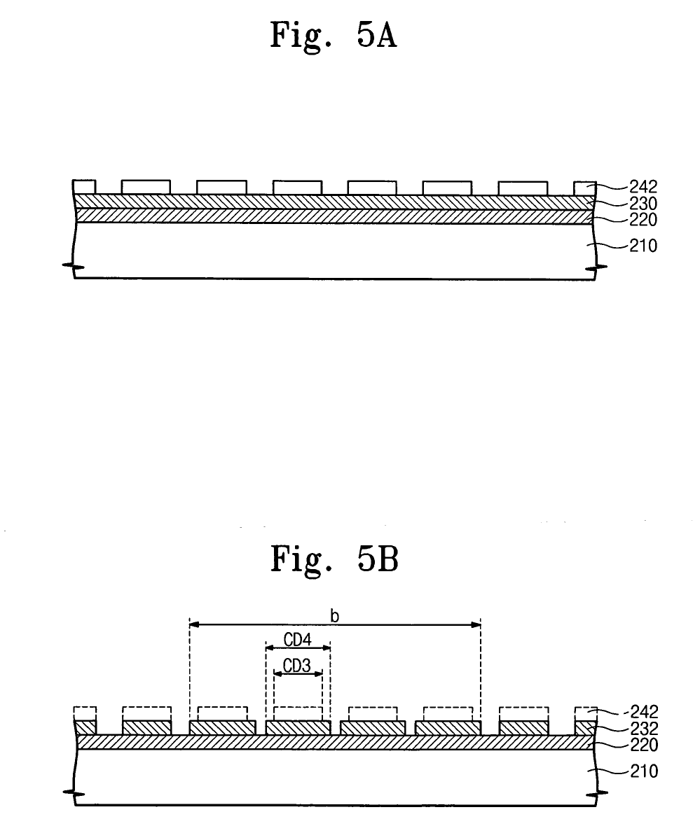

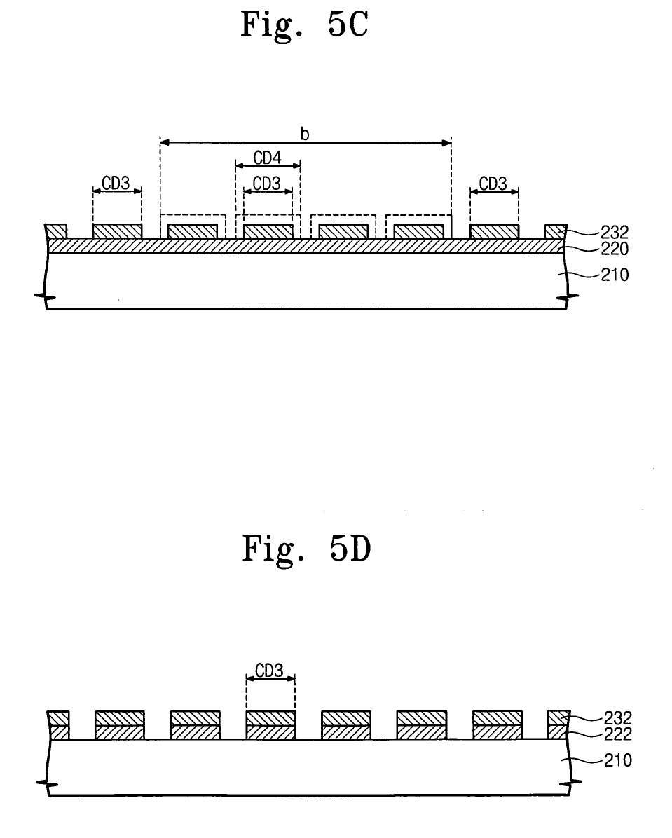

FIG. 4 illustrates a flow chart of a method of fabricating a photomask according to another embodiment. FIGS. 5A through 5D illustrate sectional views of stages in a method of fabricating a photomask according to the embodiment.

Referring to FIGS. 4 and 5A, a substrate 210 may be prepared (S210). The substrate 210 may include, e.g., a photomask substrate for a semiconductor exposure process. The substrate 210 may be formed of, e.g., quartz. The photomask fabricated by the method of the present embodiment may be, e.g., a phase shift mask (PSM).

A phase shift layer 220, a light-shielding layer 230, and a photoresist pattern 242 may be sequentially formed on the substrate 210 (S220). The forming of the phase shift layer 220 may include forming a layer capable of shifting the phase of light at a predetermined angle, e.g., 180°, on the substrate 210. The forming of the phase shift layer 220 may include, e.g., forming a molybdenum silicon nitride (MoSiN) layer on the substrate 210. The forming of the light-shielding layer 230 may include, e.g., forming a chromium (Cr) layer on the phase shift layer 220.

Referring to FIGS. 4 and 5B, a light-shielding pattern 232 may be formed on the substrate 210 (S230). The forming of the light-shielding pattern 232 may include, e.g., removing a portion of the light-shielding layer 230 to expose portions of the substrate 210. The removing a portion of the light-shielding layer 230 may include, e.g., dry-etching the light-shielding layer 230 using the photoresist pattern 242 as an etch mask. After formation of the light-shielding pattern 232, the photoresist pattern 242 may be removed (S240). Meanwhile, the light-shielding pattern 232 formed through the above process may have a critical dimension (CD) deviating from a predetermined CD range. For example, a region ‘b’ having the light-shielding pattern 232 with a critical dimension CD4 greater than the predetermined critical dimension CD3 (hereinafter, “correction region”) may be present on the substrate 210.

Then, it may be determined whether the CD of the light-shielding pattern 232 on the substrate 210 satisfies the predetermined CD range (S250). For example, a CD measurement device (not illustrated) may measure the CD of the light-shielding pattern 232. The data measured by the CD measurement device may be transmitted to a controller (not illustrated). The controller may determine whether the CD of the light-shielding pattern 232 measured by the CD measurement device satisfies the predetermined CD range. For example, the controller may determine whether the measured CD of the light-shielding pattern 232 deviates from the predetermined CD range by comparing the data received from the CD measurement device with reference data.

Referring to FIGS. 4 and 5C, if the CD of the light-shielding pattern 232 measured by the CD measurement device deviates from the predetermined CD range, the CD of the light-shielding pattern 232 may be corrected (S260). For example, if the measured CD of the light-shielding pattern 232 deviates from the predetermined CD range, the controller may then liquid-treat the pre-photomask. The liquid-treating of the pre-photomask may include, e.g., supplying an etchant onto the pre-photomask. The etchant may isotropically etch the light-shielding pattern 232 in the correction region ‘b’. Accordingly, the critical dimension CD4 of the light-shielding pattern 232 in the correction region ‘b’ may decrease to the predetermined critical dimension CD3. In an implementation, the liquid-treating of the pre-photomask may be performed through a single-wafer substrate treating process. The supplying of the etchant onto the photomask may be performed using a nozzle. The single-wafer substrate treating process and the etchant supplying process using the nozzle may be identical or similar to those described with reference to FIGS. 3A and 3B, and thus a repeated description thereof will be omitted.

Referring to FIGS. 4 and 5D, if the CD of the light-shielding pattern 232 measured by the CD measurement device satisfies the predetermined critical dimension CD3, a phase shift pattern 222 may then be formed on the substrate 210. The phase shift layer 220 may be etched using the light-shielding pattern 232 satisfying the predetermined critical dimension CD3 as an etch mask. Accordingly, the phase shift pattern 222 and the light-shielding pattern 232, which may have the same CD (CD3), may be formed on the substrate 210. The light-shielding pattern 232 may then be removed (S280). After removal of the light-shielding pattern 232, the photomask fabrication may be completed (S290).

In a photomask fabrication process, the CD of the light-shielding pattern formed in the photomask may deviate from a predetermined CD range. The photolithography process may be interrupted until the photomask fabrication equipment is readjusted. As described above, the methods of fabricating a photomask according to an embodiment may effectively correct the CD of a light-shielding pattern deviating from a predetermined CD range, thus making it possible to increase the efficiency of a photomask fabrication process.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of fabricating a photomask, comprising:
forming a light-shielding pattern on a substrate;
determining whether a critical dimension (CD) of the light-shielding pattern deviates by at least a predetermined amount from a predetermined CD range; and
correcting the CD of the light-shielding pattern if the CD of the light-shielding pattern deviates by at least the predetermined amount from the predetermined CD range,
wherein the correcting the CD of the light-shielding pattern includes selectively liquid-treating the light-shielding pattern having a CD deviating by at least the predetermined amount from the predetermined CD range.

2. The method as claimed in claim 1, wherein the liquid-treating of the light-shielding pattern is performed using a nozzle that has a sprayer configured to spray a liquid onto the substrate and an inhaler configured to inhale the liquid on the substrate.

3. The method as claimed in claim 1, wherein the determining whether the CD of the light-shielding pattern deviates by at least the predetermined amount from the predetermined CD range includes determining whether the CD of the light-shielding pattern is greater by at least the predetermined amount than a predetermined CD.

4. The method as claimed in claim 1, wherein the liquid-treating of the light-shielding pattern includes supplying an etchant onto the substrate, the etchant including at least one of sulfuric acid (H₂SO₄), hydrogen peroxide (H₂O₂), and water including a gas dissolved therein including at least one of hydrogen (H₂), ozone (O₃), and ammonia (NH₃).

5. The method as claimed in claim 4, wherein the etchant reduces the CD of the light-shielding pattern.

6. The method as claimed in claim 1, wherein the forming the light-shielding pattern on the substrate includes:
sequentially forming a light-shielding layer and a photoresist pattern on the substrate; and
etching the light-shielding layer using the photoresist pattern as an etch mask.

7. The method as claimed in claim 1, wherein the forming the light-shielding pattern on the substrate includes:
forming a phase shift layer, a light-shielding layer, and a photoresist pattern on the substrate; and
etching the light-shielding layer using the photoresist pattern as an etch mask.

8. The method as claimed in claim 7, further comprising forming a phase-shift pattern by etching the phase shift layer after the liquid-treating the light-shielding pattern using the light-shielding pattern, which has been corrected to satisfy the predetermined CD range, as an etch mask.

9. The method as claimed in claim 8, further comprising removing the light-shielding pattern from the phase-shift pattern.

10. A method of fabricating a photomask, comprising:
forming light-shielding patterns including a first light-shielding pattern and a second light-shielding pattern on a substrate; and
correcting the second light-shielding patterns by supplying an etchant onto the substrate,
wherein:
the first light-shielding pattern satisfies a predetermined CD range and the second light-shielding pattern deviates by at least a predetermined amount from the predetermined CD range, and
the correcting the light-shielding patterns includes removing the etchant supplied to the first light-shielding pattern and reducing a CD of the second light-shielding pattern with the etchant.

11. The method as claimed in claim 10, wherein the removing the etchant supplied to the first light-shielding pattern is performed using a nozzle with an inhaler configured to inhale the etchant.
